(19) United States
(12) Patent Application Publication
(10) Pub. No.: US 2012/0197568 A1
(43) Pub. Date: Aug. 2, 2012

(54) METHOD OF DETERMINING LOAD CAPACITANCE OF CRYSTAL OSCILLATION CIRCUIT, AND ELECTRONIC APPARATUS USING THE SAME

(76) Inventor: Hiroyuki Souma, Chiba-shi (JP)

(21) Appl. No.: 13/360,214

(22) Filed: Jan. 27, 2012

(30) Foreign Application Priority Data
Jan. 27, 2011 (JP) 2011-015446

(51) Int. Cl. G06F 19/00; G01R 27/26

(52) U.S. Cl. 702/65; 324/658

(57) ABSTRACT

There is provided an oscillation circuit using a crystal vibrator including means A for obtaining an oscillation activation time Ts (Ts0) from an oscillation margin M by using a relational equation between the oscillation activation time Ts and the oscillation margin M or a relational graph thereof; means B for obtaining a relational equation between the oscillation activation time Ts and a load capacitance CL in an arbitrary driving current value Ios from the relational equation between the oscillation activation time Ts and the load capacitance CL, and the driving current value Ios; and means C for determining the load capacitance CL corresponding to the oscillation activation time Ts0 obtained by the means A, by using the relational equation between the oscillation activation time Ts and the load capacitance CL, which is obtained by the means B.

### RELATED APPLICATIONS

This application claims priority under 35 U.S.C. §119 to Japanese Patent Application No. 2011-015446 filed on Jan. 27, 2011, the entire content of which is hereby incorporated by reference.

### BACKGROUND OF THE INVENTION

1. Field of the Invention

The present invention relates to a method of realizing a low power-consumption crystal oscillation circuit, and more particularly, to a method of determining the load capacitance that makes up the crystal oscillation circuit, and an electronic apparatus using the same.

2. Description of the Related Art

In regard to a portable apparatus such as a timepiece and a cellular phone, because of demands for long-term operation of the apparatus without charging and a reduction in the frequency of charging the installed battery, a reduction in the driving power of an oscillation circuit to which a piezoelectric element such as a crystal vibrator or the like, which is used for the apparatus, is assembled, and ultra-low power-consumption in the oscillation circuit standby state (in a state where the oscillation circuit has been oscillated and an unloaded state) are further requested.

A typical oscillation circuit using a crystal vibrator, includes a CMOS inverter, a crystal vibrator connected between an input terminal and an output terminal of the CMOS inverter, and capacitative elements.

Recently, in an oscillation circuit that is mounted in a portable apparatus or the like, lower power consumption is requested, but as a result thereof, it is necessary to decrease the driving current of a crystal vibrator in the oscillation circuit. Therefore, making the mutual conductance Gm of a CMOS inverter in the oscillation circuit small is considered. However, when the mutual conductance Gm is decreased, an oscillation margin M of the oscillation circuit may be decreased.

To maintain the oscillation margin M of the oscillation circuit even when the mutual conductance Gm is decreased, the crystal vibrator of the oscillation circuit have a load capacitance CL that is appropriate for the specification of lower power consumption requested with respect to the IC of a microcomputer to which the oscillation circuit is assembled. That is, the present applicant has suggested decreasing the load capacitance CL, that is, the lowering of CL (3 to 5 pF) with respect to 12.5 pF that is a load capacitance CL of a crystal vibrator that has been used in the related art (refer to JP-A-2008-205658).

However, when the load capacitance CL is decreased, a problem, which is related to the capacitance tolerance of the load capacitance CL and the frequency deviation Δf of the oscillation frequency, becomes significant. For example, in regard to safety Δf (ppm) of the oscillation frequency in a case where the load capacitance CL varies by ΔC (±5%) that is the range of a normal capacitance tolerance, when the load capacitance CL is 12.5 pF, the safety Δf of the oscillation frequency becomes 7.3 ppm at ΔC of 1.25 pF, when the load capacitance CL is 6 pF, the safety Δf of the oscillation frequency becomes 13.2 ppm at ΔC of 0.6 pF, and when the load capacitance CL is 3 pF, the safety Δf of the oscillation frequency becomes 20.5 ppm at ΔC of 0.3 pF.

That is, in the load capacitance CL (3 pF), the frequency deviation increases by 2.8 times compared to 12.5 pF in the related art, such that to realize the low capacitance (low CL), it is necessary to improve the safety of the oscillation frequency with respect to the capacitance tolerance of the load capacitance CL.

In addition, the decrease in the load capacitance CL may contribute to lower power consumption in the crystal oscillation circuit, and therefore greatly contribute to the saving of power of an electronic apparatus that uses the crystal oscillation circuit.

### SUMMARY OF THE INVENTION

When the load capacitance CL is decreased, lower power consumption of the crystal oscillation circuit may be realized. However, even when the lowering of CL is realized, the relationship with an oscillation activation time Ts is unclear, such that the time taken to activate in actual use becomes a problem. When there is information for whether oscillation occurs or information for the load capacitance appropriate to obtain a predetermined Ts, a design is easily made. Further, in practice, even when a crystal vibrator having an arbitrarily low CL value is incorporated into an oscillation circuit and is used, it is possible to use it without concern. Therefore, it is desired to know the relationship between the oscillation activation time Ts and the load capacitance CL.

An object of the invention is to provide a method of determining the value of a load capacitance CL appropriate for a desired oscillation activation time Ts by clarifying the relationship between the oscillation activation time Ts of an oscillation circuit using a crystal vibrator and the load capacitance CL. Specifically, this object is realized by the following methods.

(1) According to a first aspect of the invention, there is provided a method of determining a load capacitance CL in an oscillation circuit using a crystal vibrator. The method includes means A for obtaining an oscillation activation time Ts (Ts0) from an oscillation margin M by using a relational equation between the oscillation activation time Ts and the oscillation margin M or a relational graph thereof; means B for obtaining a relational equation between the oscillation activation time Ts and a load capacitance CL in an arbitrary driving current value Ios from the relational equation between the oscillation activation time Ts and the load capacitance CL, and the driving current value Ios; and means C for determining the load capacitance CL corresponding to the oscillation activation time Ts0 obtained by the means A, by using the relational equation between the oscillation activation time Ts and the load capacitance CL, which is obtained by the means B.

(2) According to a second aspect of the invention, the relational equation between the oscillation activation time Ts and the oscillation margin M in the means A may be represented by the following equation.

M=a/(Ts)^{b} (here, a and b are constants)

(3) According to a third aspect of the invention, the relational equation between the oscillation activation time Ts and the oscillation margin M in the means A may be represented by the following equation.

M=3.74(Ts)^{-0.70}

(4) According to a fourth aspect of the invention, the relational equation between the oscillation activation time Ts and the load capacitance CL in the means B may be represented by the following equation.

Ts=c*(CL)²+d*(CL)+e(here, c, d, and e are constants)

(5) According to a fifth aspect of the invention, in the means B, the relational equation between the oscillation activation time Ts and the load capacitance CL in at least two driving current values Ios (Ios1 and Ios2) that are obtained beforehand may be represented by the following equations (1) and (2),

Ts=c1*(CL)²+d1*(CL)+e1(Ios=Ios1) (1),

Ts=c2*(CL)²+d2*(CL)+e2(Ios=Ios2) (2),

a relational equation between the oscillation activation time Ts and the load capacitance CL in an arbitrary driving current value Ios, that is, the following equation (3) may be determined by using equations (1) and (2),

Ts=c0*(CL)²+d0*(CL)+e0(in a case where the driving current value Ios is an arbitrarily value(Ios0) (3), and

in the means C, the load capacitance CL may be determined from the oscillation activation time Ts0 obtained by equation (3) and the means A.

(6) According to a sixth aspect of the invention, in the means B, the relational equation between the oscillation activation time Ts and the load capacitance CL may be represented by the following equations (4) to (6), the driving current value Ios being used as a parameter,

Ts=0.0191(CL)²+0.0487(CL)+0.0623(when Ios=160 nA) (4),

Ts=0.0424(CL)²−0.0030(CL)+0.1240(when Ios=95 nA) (5),

Ts=0.0558(CL)²+0.0316(CL)+0.1141(when Ios=70 nA) (6),

a relational equation between the oscillation activation time Ts and the load capacitance CL in an arbitrary driving current value Ios, that is, the following equation (7) may be obtained (that is, α, β, and γ in equation (4) are determined) by using equations (4) and (5) when the driving current value Ios of the oscillation circuit that is used satisfies a relationship of Ios≧95 nA, and equations (5) and (6) when the driving current value Ios satisfies a relationship of Ios≦95 nA,

Ts=α(CL)²+β(CL)+γ(in a case where the driving current value Ios is an arbitrarily value(Ios0)) (7), and

in the means C, the load capacitance CL may be determined by using equation (7) obtained by the means B.

(7) According to a seventh aspect of the invention, there is provided an electronic apparatus including a crystal oscillation circuit that is mounted in the electronic apparatus, and has a load capacitance determined by the method of determining a load capacitance CL according to any one of first to sixth aspects of the invention.

According to the invention, it becomes clear for the first time that a quadratic relationship is present between an oscillation activation time Ts and a load capacitance CL, when a driving current value Ios of an oscillation circuit is used as a parameter. That is, it becomes clear for the first time that the following equation of Ts=α*(CL)²+β(CL)+γ (α, β, and γ are constants) is established. A necessary oscillation activation time Ts0 is obtained from an oscillation margin M0 that is a requested value by using the relational equation between the oscillation margin M and the oscillation activation time Ts or a relational graph thereof. Furthermore, the load capacitance CL of an oscillation circuit may be determined from the Ts0 by using the following relational equation of Ts=α*(CL)²+β(CL)+γ, which was discovered by the present inventor. Therefore, at first, it is not necessary to determine the load capacitance CL of the oscillation circuit, and the CL value of the oscillation circuit may be automatically determined by only determining the design values of the driving current Ios and the oscillation margin M of the oscillation circuit, and as a result thereof, the design may be easily made. In addition, the Ts value becomes 1.0 second or less, such that the lowering of CL of a crystal oscillation circuit may be realized, and as a result thereof, lower power consumption of the crystal oscillation circuit and lowered power consumption of an electronic apparatus in which the crystal oscillation circuit is assembled may be realized.

### BRIEF DESCRIPTION OF THE DRAWINGS

FIG. 1 is a diagram illustrating the oscillation circuit using the crystal vibrator;

FIG. 2 is a diagram illustrating a crystal vibrator-side equivalent circuit between input and output terminals XCIN and XCOUT in FIG. 3;

FIG. 3 is a diagram illustrating capacitors making up a load capacitance CL; and

FIG. 4 is a diagram illustrating a relationship between the driving current and the load capacitance CL in the crystal oscillation circuit.

FIG. 5 is a diagram illustrating a relationship between a CL value and an oscillation activation time Ts in an oscillation circuit having various CL values by using a driving current Ios of an oscillation circuit as a parameter;

FIG. 6 is a graph illustrating a relationship between an oscillation margin M and the oscillation activation time Ts in the oscillation circuit having a crystal vibrator;

### DETAILED DESCRIPTION OF THE PREFERRED EMBODIMENTS

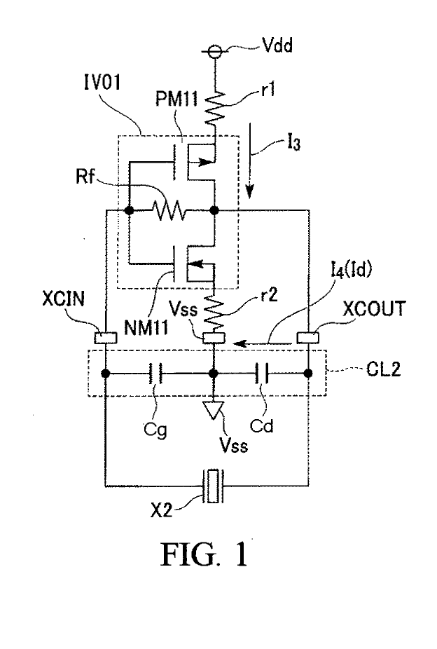

FIG. 1 shows an oscillation circuit using a crystal vibrator, and the oscillation circuit includes a CMOS inverter IV01 that is an inverting amplifier, a crystal vibrator X2 connected between an input terminal XCIN and an output terminal XCOUT of the CMOS inverter IV01, a capacitative element that is connected between the input terminal XCIN of the CMOS inverter IV01 and a power source terminal of a ground potential Vss and makes up a load capacitance Cg, and a capacitative element that is connected between the output terminal XCOUT of the CMOS inverter IV01 and the power source terminal of the ground potential Vss and makes up a load capacitance Cd.

In addition, the CMOS inverter IV01 includes, a PMOS transistor PM11 that is serially connected between a first power source terminal with which a power source voltage Vdd is shared and a second power source terminal to which a ground potential is supplied, a CMOS inverter including an NMOS transistor NM11, and a feedback resistor RE

Driving current adjusting resistor elements r1 and r2 that restrict a driving current for exciting the crystal vibrator X2 are connected between the source of the PMOS transistor PM11 of the CMOS inverter IV01 and the first power source terminal, and between the NMOS transistor NM11 of the CMOS inverter IV02 and the second power source terminal.

In order to achieve lower power consumption, the driving current of a crystal vibrator in the oscillation circuit may decrease and making the mutual conductance Gm of a CMOS inverter in the oscillation circuit small is considered. However, as the mutual conductance Gm decreases, an oscillation margin M of the oscillation circuit may decrease.

The oscillation margin M of the oscillation circuit is given by the following equation (1).

M=|−Gm|/{(ω²Cg·Cd)*(1/R1(max))}=+RL/R1(max) (1)

Here, ω represents the angular frequency of an oscillation frequency, RL represents negative resistance, R1 (max) represents the maximum value of the effective resistance R1 of the crystal vibrator, and commonly, a value of 5 or more is requested for the oscillation margin M.

In equation (1), the effective resistance R1 of the crystal vibrator is a value determined from a request for miniaturization of the crystal vibrator, such that it is difficult to make the effective resistance R1 too small. Therefore, to maintain the oscillation margin M of the oscillation circuit even when the mutual conductance Gm is decreased, it becomes clear that it is preferable to decrease the value of a load capacitance Cg and/or Cd of a condenser making up a load capacitance that is externally attached to the CMOS inverter.

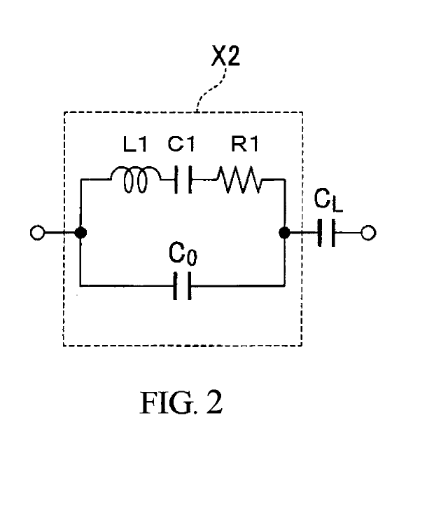

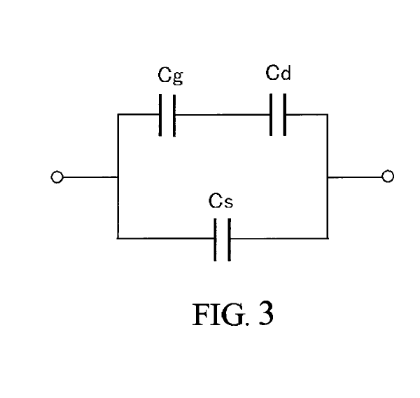

A crystal vibrator-side equivalent circuit between the input and output terminals XCIN and XCOUT in FIG. 1 corresponds to FIG. 2. A load capacitance CL is connected in series to the crystal vibrator X2, and the crystal vibrator is represented by a circuit in which an inter-electrode capacitor C0 is connected in parallel to a serial resonance circuit of an inductance L1, a capacitance C1, and a resistance R1, which equivalently represents a mechanical resonance generated through the piezoelectric effect. In addition, various kinds of stray capacitance are present between the input and output terminals XCIN and XCOUT due to a CMOS semiconductor substrate, a signal wiring, or the like, but when a (composite) stray capacitance thereof is set to a stray capacitance Cs, as shown in FIG. 3, the load capacitance CL is connected in parallel to an external (externally attached) capacitors Cg and Cd that are connected in series to the stray capacitor Cs.

Therefore, the following equation (2) is established.

CL=Cs+Cg*Cd/(Cg+Cd) (2)

When externally attached capacitative elements Cg and Cd are selected in conformity with the oscillation frequency in such a manner that the CL value (2 to 6 pF) satisfying equation (2) is obtained, it is possible to improve the stability of the oscillation frequency. That is, the load capacitance CL is the sum of the stray capacitance Cs and an external capacitance Cext {=Cg*Cd/(Cg+Cd)}, such that when the value of the external capacitance Cext is set to become to the difference between the load capacitance CL and the stray capacitance Cs, equation (2) is satisfied, and therefore it means that the load capacitance CL of the crystal vibrator and the load capacitance at the oscillation circuit side seen from the crystal vibrator are matched.

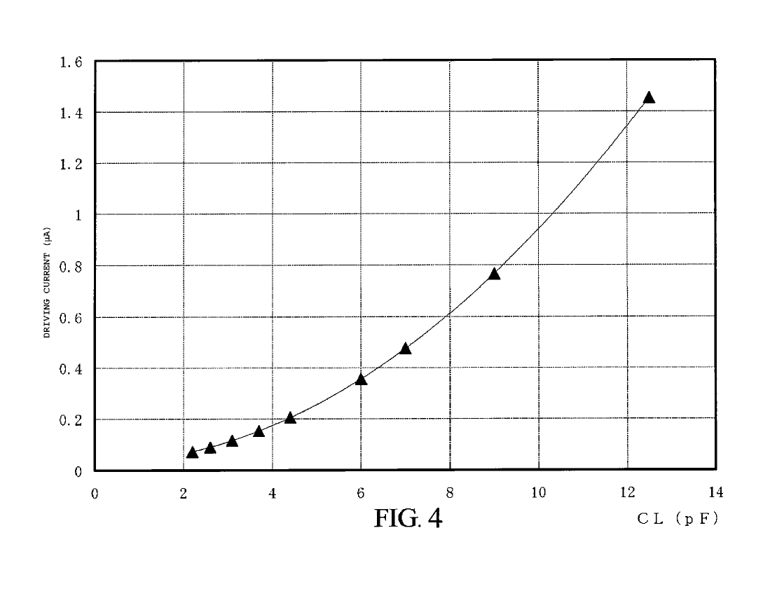

FIG. 4 shows a diagram illustrating a relationship between a driving current and the load capacitance CL in the crystal oscillation circuit. From the relationship, it can be seen that as the load capacitance becomes smaller, the driving current decreases significantly. For example, the driving current of the load capacitance 12.5 pF that is used in the related art is approximately 1.5 μA, but the driving current of the load capacitance 2.2 pF becomes 0.073 μA, and therefore the driving current decreases to approximately 5%. In this manner, the decrease in the load capacitance CL may contribute to lower power consumption in the crystal oscillation circuit, and therefore greatly contribute to the saving of power of an electronic apparatus that uses the crystal oscillation circuit.

An object of the invention is to provide a method of determining the value of a load capacitance CL appropriate for a desired oscillation activation time by clarifying a relationship between the oscillation activation time of an oscillation circuit using a crystal vibrator and the load capacitance CL.

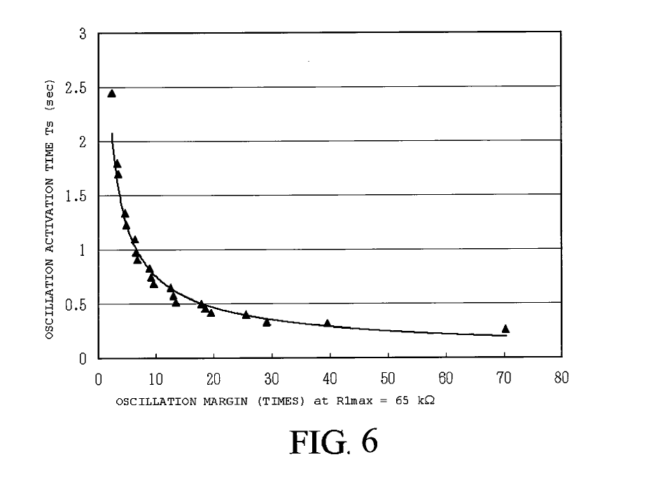

The oscillation activation time is the time taken until a waveform of oscillation becomes stable after an oscillation circuit having a crystal vibrator is attached to an apparatus and power is supplied, but the oscillation activation time is defined as the time taken until reaching 90% of the amplitude of a normal waveform from an aspect of measurement. FIG. 6 illustrates a relationship between the above-described oscillation margin M and the oscillation activation time Ts in various oscillation circuits having various crystal vibrators. From FIG. 6, it can be seen that as the oscillation activation time increases, the oscillation margin M decreases. As can be seen from this drawing, when M is not five or more, the oscillation activation time is lengthened to one second or more and becomes irregular, and as a result thereof, a problem may occur in actual use.

From FIG. 6, it can be seen that a relational equation of Ts=3.74M^{-0.70} is obtained, and the correlation coefficient R is 0.985 and a very good correlation is shown. The above-described relational equation was obtained from the present data, but generally, a relationship of Ts=a*M^{-b} is present (here, a and b is positive constants). The oscillation margin M is a value determined by a designer or the like from the safety of an oscillator. a and b may be obtained from an oscillation circuit having various crystal oscillators.

In a low CL oscillation circuit in which the load capacitance CL is decreased, a large oscillation margin is obtained, and therefore it may be considered that the oscillation activation time Ts can be decreased. However, the relationship between the oscillation activation time Ts and the load capacitance CL was unclear until now. Therefore, the present inventor has measured the oscillation activation time Ts with respect to an oscillation circuit having various low CL values, and has found that the oscillation activation time Ts and the load capacitance CL have a very close correlation.

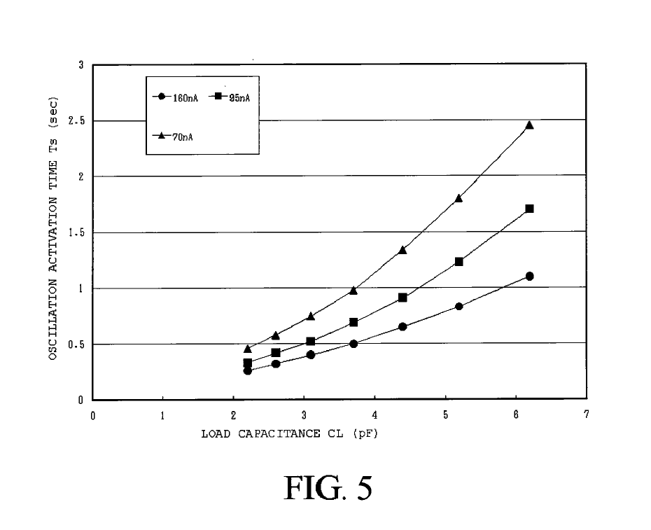

FIG. 5 shows a diagram obtained by plotting measurements of the oscillation activation time Ts with a driving current value Ios of the oscillation circuit used as a parameter, with respect to an oscillation circuit having various values of a load capacitance CL (where a load capacitance value is less than 7 pF). As can be seen from this drawing, regardless of the magnitude of the driving current value Ios, as the oscillation activation time Ts is shortened, the load capacitance CL decreases. On the contrary, when a low load capacitance CL is used, the oscillation activation time Ts may be shortened. Referring to the relationship with the oscillation margin M shown in FIG. 6, when a low load capacitance CL is used, the oscillation margin M becomes large. This may be explained as follows. That is, from a relationship of a negative resistance of RL=−Gm/(2ωCL)², when it becomes a low CL, the negative resistance RL increases, and M=RL/R1max increases according to the defined equation (1) of the oscillation margin M. In a case where a high load capacitance (CL>10 pF, for example, 12.5 pF) in the related art is used, a method of increasing the oscillation margin M by increasing the driving current Ios is used, such that it is difficult to decrease power consumption. However, a low CL method pursued by the present applicant is used, it is possible to increase the oscillation margin M by making the value of the load capacitance CL small, and furthermore the oscillation activation time Ts may be simply made to be one second or less (in FIG. 5, 0.5 seconds or less is possible), and as a result thereof, high speed activation may be realized. That is, the low CL oscillator may easily realize a high-speed and power saving oscillation circuit.

From FIG. 5, a polynomial expression is made to approximate this curved line, when Ios=160 nA, Ts (sec)=0.0191CL²+0.0487CL+0.0623 (a correlation coefficient R=0.9999), when Ios=95 nA, Ts (sec)=0.0424CL²−0.0030CL+0.1240 (a correlation coefficient R=0.9999), and when Ios=70 nA, Ts (sec)=0.0558CL²+0.0316CL+0.1141 (a correlation coefficient R=0.9999) are established. Therefore, a quadratic equation having a very strong correlation is obtained. That is, a coefficient of a relational equation is different depending on Ios, but a relationship of Ts=α*CL²β*CL+γ is discovered. This is a new discovery, and it is possible to determine the value of the load capacitance CL for obtaining a desired oscillation activation time Ts by using this relational equation. From the graph in FIG. 5, in each driving current, it is possible to realize a high-speed activation crystal oscillator that satisfies a specification of Ts<0.5 seconds. However, it is necessary that the oscillation activation time Ts does not exceed a time constant τ0 of an oscillator (in the case of the crystal oscillator, 0.3 seconds).

Hereinafter, a specific method of the invention will be described in detail. First, the driving current value Ios0 and the oscillation margin M0 of the oscillation circuit are determined. These values may be selected by a designer depending on the electronic apparatus to which the oscillation circuit is connected (for example, a portable terminal such as a cellular phone, and an electronic book). Next, the oscillation activation time Ts (Ts0) is obtained from a relational equation Ts=a*M^{-b}, which can be obtained beforehand by using a relational equation (or a graph) of FIG. 6, or the like. That is, an equation of Ts0=a*M0^{-b} is obtained. In a case where a relational equation which personally obtains is not present, Ts=3.74M^{-0.70} may be used. (At this time, Ts0=3.74M0^{-0.70}). In addition, an approximate Ts0 may be obtained from a relational graph between Ts and M of FIG. 5 or the like which personally makes. In a case where a relational graph which personally makes is not present, FIG. 5 may be used.

Next, data such as FIG. 5 is obtained beforehand. A relationship between the oscillation activation time Ts and the load capacitance CL is obtained, in which two values of a driving current Ios at the minimum are set as a parameter. A very strong correlation is established, 3 to 4 pieces of data at the minimum with respect to each driving current Ios may be sufficient. From these, the following two quadratic equations at the minimum are obtained (Ios1>Ios2).

Ts=c1*(CL)²+d1*(CL)+e1(Ios=Ios1)

Ts=c2*(CL)²+d2*(CL)+e2(Ios=Ios2)

In addition, with respect to three values of the load capacitance CL (x1, x2, and x3), through a simple proportion, a curved line in the driving current Ios0, that is, Ts=c0*(CL)²+d0*(CL)+e0 (Ios=Ios0) is obtained. For example, from Ts(x1) at Ios1=c1*(x1)²+d1*(x1)+e1, and Ts(x1) at Ios2=c2*(x2)²+d2*(x2)+e2, Ts(x1) at Ios0={(Ios0-Ios1)/(Ios1-Ios2)}*(Ts(x1) at Ios1−Ts(x1) at Ios2)+Ts(x1) at Ios1 is obtained. That is, calculation is performed on the assumption that the oscillation activation time Ts is proportional to the value of the driving current Ios0. In this manner, Ts(x2) at Ios0 and Ts(x3) at Ios0 are obtained. From these three sets of values, that is, (x1, Ts(x1) at Ios0), (x2, Ts(x2) at Ios0), and (x3, Ts(x3) at Ios0), an equation of the oscillation activation time Ts with respect to the driving current Ios0, that is, the oscillation activation time Ts=c0*(CL)²+d0*(CL)+e0 (Ios=Ios0) is obtained. (c0, d0, and e0 are determined). Based on these, the value of the load capacitance CL can be obtained from a quadratic equation of Ts0=C0*(CL)²+d0*(CL)+e0 to which the oscillation activation time Ts0 obtained from the relational equation between the oscillation activation time Ts and the oscillation margin M or a relational graph thereof is substituted.

In a case where Ios0≧Ios1 or Ios0≦Ios2, that is, an arbitrary driving current Ios0 is present at the outside of the driving current Ios1 or the driving current Ios2, poor accuracy is obtained from this method, but in a case where Ios1≧Ios≧Ios2, that is, the driving current Ios0 is present between the driving currents Ios1 and Ios2, good accuracy is obtained (this is because a simple proportion is used). Particularly, when the driving current Ios1 and the driving current Ios2 approach each other, an accurate value of the load capacitance CL can be obtained with respect to the oscillation activation time Ts0. Similarly to FIG. 5, when a relational equation with respect to three sets of values of the driving current Ios can be obtained, in a case where the driving current Ios is present between these values (that is, the driving current Ios is present between 160 nA and 75 nA), it is possible to obtain an accurate value of the load capacitance CL.

That is, in means B of the invention, a relational equation between the oscillation activation time Ts and the load capacitance CL with a driving current value Ios used as a parameter is as follows.

Ts=0.0191(CL)²+0.0487(CL)+0.0623(when Ios=160 nA)

Ts=0.0424(CL)²−0.0030(CL)+0.1240(when Ios=95 nA)

Ts=0.0558(CL)²+0.0316(CL)+0.1141(when Ios=70 nA)

Therefore, when the driving current value of the oscillation circuit that is used is set to Ios0, in the case of Ios≧95 nA, the first and second equations are used, and in the case of Ios≦95 nA, the second and third equations are used, and through a simple proportion, a relational equation at the driving current value of Ios=Ios0, that is, Ts=α(CL)²β(CL)+γ (when Ios=Ios0) is obtained (that is, α, β, and γ are determined), and as a result thereof, the load capacitance CL is determined in means C of the invention.

As described above, in the invention, the oscillation activation time Ts0 corresponding to the oscillation margin M0 is obtained from a relational curve (equation) between the oscillation margin M and the oscillation activation time Ts or a relational graph thereof. In addition, Ts0 is substituted in a quadratic curve of Ts=α(CL)²+β(CL)+γ, which is obtained from the relational curve (equation) between the oscillation activation time Ts and the load capacitance CL and as a result thereof, it is possible to determine the value of the load capacitance CL.

The crystal oscillation circuit determined by the above-described method of determining the value of a load capacitance CL of the invention may be mounted and applied to a crystal oscillator or an electronic apparatus. For example, a battery driven-type electronic apparatus such as a timepiece, a cellular phone, a portable terminal, and a notebook PC may be exemplified. In addition, the oscillation circuit may be applied to various kinds of electronic apparatuses such as in-vehicle electronic apparatuses and household electrical appliances including a television, a refrigerator, an air conditioner, or the like, in which saving of energy or saving of power is required.

The present invention may be used for an oscillation circuit using a crystal vibrator. Particularly, the invention is effective for designing low power-consumption oscillation circuit. In addition, the present invention may be used for a crystal oscillator, an electronic apparatus, or the like, in which the oscillation circuit using the crystal vibrator is mounted.

What is claimed is:

1. A method for determining a load capacitance (CL) in an oscillation circuit using a crystal vibrator, comprising:
selecting an oscillation margin M and a default driving current value Ios0 for an oscillation circuit based on an apparatus to which the oscillation circuit is connected;
obtaining a default oscillation activation time Ts0 corresponding to the oscillation margin M by using a predetermined relationship between the oscillation activation time Ts and the oscillation margin M;
obtaining a relational equation between an oscillation activation time Ts and a load capacitance CL using a driving current value Ios as a parameter, wherein the default driving current value Ios0 ranges between a lower value and an upper value of the driving current value Ios, and the oscillation activation time Ts is proportional to the driving current value Ios; and
determining the load capacitance CL corresponding to the oscillation activation time Ts0, by using the relational equation between the oscillator activation time Ts and the load capacitance CL and using the obtained default oscillation activation time Ts0.

2. The method of claim 1, wherein the relational equation between the oscillation activation time Ts and the oscillation margin M is:
M=a/(Ts)^{b}(here, a and b are constants).

3. The method of claim 2, wherein the relational equation between the oscillation activation time Ts and the oscillation margin M is:
M=3.74(Ts)^{-0.70}

4. The method of claim 1, wherein the relational equation between the oscillation activation time Ts and the load capacitance CL is:
Ts=c*(CL)²+d*(CL)+e(here, c, d, and e are constants)

5. The method of claim 4, wherein the step of obtaining the relational equation between the oscillation activation time Ts and the load capacitance CL comprises:
obtaining the relational equation represented by the following equations (1) and (2), wherein the driving current value Ios comprises a first driving current value Ios1 and a second driving current value Ios2:
Ts=c1*(CL)²+d1*(CL)+e1(Ios=Ios1) (1),
Ts=c2*(CL)²+d2*(CL)+e2(Ios=Ios2) (2).

6. The method of claim 5, wherein the step of obtaining the relational equation between the oscillation activation time Ts and the load capacitance CL comprises:
obtaining the relational equation represented by the following equations (3) wherein the driving current value Ios comprises a third driving current value Ios3:
Ts=c3*(CL)²+d3*(CL)+e3(Ios=Ios3) (3).

7. The method of claim 6, further comprising obtaining the relational equation between the default osciallation activation time Ts0 and the load capacitance CL as follows:
Ts0=c0*(CL)²+d0*(CL)+e0 (4).

8. The method of claim 7, wherein the step of determining the load capacitance CL comprises determining the load capacitance CL based on the equations (1)-(2) and (4) and the obtained default oscillation activation time Ts0.

9. The method of claim 7, wherein the step of determining the load capacitance CL comprises determining the load capacitance CL based on the equations (1)-(4) and the obtained default oscillation activation time Ts0.

10. The method of claim 1, wherein the step of obtaining a relational equation between an oscillation activation time Ts and a load capacitance CL comprises obtaining the following equations:
Ts=0.0191(CL)²+0.0487(CL)+0.0623(when Ios=160 nA) (5);
Ts=0.0424(CL)²−0.0030(CL)+0.1240(when Ios=95 nA) (6);
and
Ts=0.0558(CL)²+0.0316(CL)+0.1141(when Ios=70 nA) (7),
wherein the step of determining the load capacitance CL comprises:
obtaining the following equation (8) by using equations (5) and (6) when the default driving current value Ios0 of the oscillation circuit that is used satisfies a relationship of Ios0≧95 nA, and equations (6) and (7) when the driving current value Ios0 satisfies a relationship of Ios0≦95 nA,
Ts0=α(CL)²+β(CL)+γ for the default driving current value Ios0 (8),
wherein α, β, and γ in equation (8) are constants, and
determining the load capacitance CL corresponding to the default oscillator activation time Ts0 by using the equation (8).

11. The method of claim 1, wherein the value of the load capacitance CL is automatically determined by selecting the oscillation margin M and the driving current value Ios.

12. A method for determining a load capacitance (CL) in an oscillation circuit using a crystal vibrator, comprising:
determining a quadratic relationship between an oscillation activation time Ts and a load capacitance CL using a driving current value Ios of an oscillation circuit as a parameter;
establishing an equation of Ts=α*(CL)²+β(CL)+γ(α, β, and γ are constants);
obtaining an oscillation activation time Ts0 from a predetermined oscillation margin M0 by using the relationship of M=a/(Ts)^{b} (here, a and b are constants); and
determining the load capacitance CL of the oscillation circuit by using an equation of Ts0=α*(CL)²+β(CL)+γ.

13. The method of claim 12, wherein the value of the load capacitance CL is automatically determined by selecting the predetermined oscillation margin M0 and the driving current value Ios.

14. An electronic apparatus comprising a crystal oscillation circuit mounted therein and having a load capacitance determined by the method of claim 1.

15. An electronic apparatus comprising a crystal oscillation circuit mounted therein and having a load capacitance determined by the method of claim 2.

16. An electronic apparatus comprising a crystal oscillation circuit mounted therein and having a load capacitance determined by the method of claim 4.

17. An electronic apparatus comprising a crystal oscillation circuit mounted therein and having a load capacitance determined by the method of claim 5

18. An electronic apparatus comprising a crystal oscillation circuit mounted therein and having a load capacitance determined by the method of claim 6.

19. An electronic apparatus comprising a crystal oscillation circuit mounted therein and having a load capacitance determined by the method of claim 9.

20. An electronic apparatus comprising a crystal oscillation circuit mounted therein and having a load capacitance determined by the method of claim 10.
